(19) United States
(12) Patent Application Publication
(10) Pub. No.: US 2025/0239994 A1
(43) Pub. Date: Jul. 24, 2025

(54) MULTI-BAND ACOUSTIC MULTIPLEXER FILTER CIRCUIT

(71) Applicant: Qorvo US, Inc., Greensboro, NC (US)

(72) Inventor: Nadim Khlat, Cugnaux (FR)

(21) Appl. No.: 18/970,170

(22) Filed: Dec. 5, 2024

Related U.S. Application Data
(60) Provisional application No. 63/623,512, filed on Jan. 22, 2024.

(51) Int. Cl. H03H 9/54; H03H 9/70

(52) U.S. Cl. CPC H03H 9/542; H03H 9/70; H03H 2250/00

(57) ABSTRACT

A multi-band acoustic multiplexer filter circuit is provided. The multi-band acoustic multiplexer filter circuit includes multiple single-band acoustic filters and a multi-band filter circuit that can pass a signal in multiple passbands. In embodiments disclosed herein, the single-band acoustic filters and the multi-band filter circuit can be configured to collectively attenuate the signal in some of the passbands to thereby prevent the signal from becoming a blocking signal to any other passbands (e.g., adjacent passbands). By employing the multi-band filter circuit to provide a portion of the required attenuation to the blocking signal, each of the single-band acoustic filters can be subject to more relaxed attenuation requirements, thus making it possible to reduce complexity of the single-band acoustic filters and improve overall band rejection performance of the multi-band acoustic multiplexer filter circuit.

### RELATED APPLICATIONS

This application claims the benefit of U.S. provisional patent application Ser. No. 63/623,512, filed on Jan. 22, 2024, the disclosure of which is hereby incorporated herein by reference in its entirety.

### FIELD OF THE DISCLOSURE

The technology of the disclosure relates generally to a multi-band acoustic multiplexer filter.

### BACKGROUND

Wireless devices have become increasingly common in current society. The prevalence of these wireless devices is driven in part by the many functions that are now enabled on such devices for supporting a variety of applications. In this regard, a wireless device may employ a variety of circuits and/or components (e.g., filters, transceivers, antennas, and so on) to support different numbers and/or types of applications. Accordingly, the wireless device may include a number of switches to enable dynamic and flexible couplings between the variety of circuits and/or components.

Acoustic resonators, such as Surface Acoustic Wave (SAW) resonators and Bulk Acoustic Wave (BAW) resonators, are used in many high-frequency communication applications. In particular, SAW resonators are often employed in filter networks that operate at frequencies up to 1.8 GHZ, and BAW resonators are often employed in filter networks that operate at frequencies above 1.5 GHz. Such SAW and BAW-based filters have flat passbands, steep filter skirts, and squared shoulders at the upper and lower ends of the passbands and provide excellent rejection outside of the passbands. SAW and BAW-based filters also have a relatively low insertion loss, tend to decrease in size as the frequency of operation increases, and are relatively stable over wide temperature ranges.

As such, SAW and BAW-based filters are the filter of choice for many wireless devices. Most of these wireless devices support cellular, wireless fidelity (Wi-Fi), Bluetooth, and/or near field communications on the same wireless device and, as such, pose extremely challenging filtering demands. While these demands keep raising the complexity of wireless devices, there is a constant need to improve the performance of acoustic resonators and filters that are based thereon.

### SUMMARY

Aspects disclosed in the detailed description include a multi-band acoustic multiplexer filter circuit. The multi-band acoustic multiplexer filter circuit includes multiple single-band acoustic filters and a multi-band filter circuit that can pass a signal in multiple passbands. In embodiments disclosed herein, the single-band acoustic filters and the multi-band filter circuit can be configured to collectively attenuate the signal in some of the passbands to thereby prevent the signal from becoming a blocking signal to any other passbands (e.g., adjacent passbands). By employing the multi-band filter circuit to provide a portion of the required attenuation to the blocking signal, each of the single-band acoustic filters can be subject to more relaxed attenuation requirements, thus making it possible to reduce complexity of the single-band acoustic filters and improve overall band rejection performance of the multi-band acoustic multiplexer filter circuit.

In one aspect, a multi-band acoustic multiplexer filter circuit is provided. The multi-band acoustic multiplexer filter circuit includes one or more first single-band acoustic filters. Each of the one or more first single-band acoustic filters is coupled to an intermediate common node. Each of the one or more first single-band acoustic filters is configured to pass a signal to the intermediate common node in a respective one of one or more first passbands. Each of the one or more first single-band acoustic filters is also configured to block the signal from the intermediate common node outside the respective one of the one or more first passbands. Each of the one or more first single-band acoustic filters is also configured to present a respective one of one or more first impedances at the intermediate common node to thereby attenuate the signal in any blocking passband to the respective one of the one or more first passbands. The multi-band acoustic multiplexer filter circuit also includes a multi-band filter circuit. The multi-band filter circuit is coupled between the intermediate common node and an output common node. The multi-band filter circuit is configured to receive the signal via the intermediate common node in the one or more first passbands and pass the received signal to the output common node. The multi-band filter circuit is also configured to further attenuate the received signal at the output common node in any blocking passband to the respective one of the one or more first passbands.

In another aspect, a wireless device is provided. The wireless device includes a multi-band acoustic multiplexer filter circuit. The multi-band acoustic multiplexer filter circuit includes one or more first single-band acoustic filters. Each of the one or more first single-band acoustic filters is coupled to an intermediate common node. Each of the one or more first single-band acoustic filters is configured to pass a signal to the intermediate common node in a respective one of one or more first passbands. Each of the one or more first single-band acoustic filters is also configured to block the signal from the intermediate common node outside the respective one of the one or more first passbands. Each of the one or more first single-band acoustic filters is also configured to present a respective one of one or more first impedances at the intermediate common node to thereby attenuate the signal in any blocking passband to the respective one of the one or more first passbands. The multi-band acoustic multiplexer filter circuit also includes a multi-band filter circuit. The multi-band filter circuit is coupled between the intermediate common node and an output common node. The multi-band filter circuit is configured to receive the signal via the intermediate common node in the one or more first passbands and pass the received signal to the output common node. The multi-band filter circuit is also configured to further attenuate the received signal at the output common node in any blocking passband to the respective one of the one or more first passbands.

In another aspect, a method for configuring a multi-band acoustic multiplexer filter circuit is provided. The method includes passing a signal to an intermediate common node in a respective one of one or more first passbands. The method also includes blocking the signal from the intermediate common node outside the respective one of the one or more first passbands. The method also includes presenting a respective one of one or more first impedances at the intermediate common node to thereby attenuate the signal in any blocking passband to the respective one of the one or more first passbands. The method also includes further attenuating the signal at an output common node in the any blocking passband to the respective one of the one or more first passbands.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1 is a schematic diagram of an exemplary existing multi-band acoustic multiplexer filter circuit wherein an output stage resonator in each of multiple single-band acoustic filters is coupled directly to a common node;

FIG. 2A is a schematic diagram illustrating respective passbands of the single-band acoustic filters in FIG. 1;

FIG. 2B is a schematic diagram illustrating a scenario wherein one of the single-band acoustic filters in FIG. 1 needs to present a high impedance at the common node to attenuate a blocking signal passed to the common node by another one of the single-band acoustic filters;

FIG. 3 is a schematic diagram of an exemplary multi-band acoustic multiplexer circuit wherein multiple single-band acoustic filters and a multi-band filter circuit are configured according to an embodiment of the present disclosure to collectively provide adequate out-of-band (OOB) attenuation at an output common node and in any of multiple passbands;

FIG. 4 is a schematic diagram of an exemplary multi-band acoustic multiplexer circuit wherein some of multiple single-band acoustic filters and a multi-band filter circuit are configured according to another embodiment of the present disclosure to collectively provide adequate OOB attenuation at an output common node and in any of the multiple passbands;

FIG. 5 is a schematic diagram providing an exemplary illustration of the multi-band filter circuit in the multi-band acoustic multiplexer circuits of FIGS. 3 and 4;

FIG. 6 is a schematic diagram providing an exemplary illustration of a multi-band negative capacitance circuit in the multi-band filter circuit of FIG. 5;

FIG. 7 is a schematic diagram of an exemplary user element wherein the acoustic multiplexer filter circuit of FIG. 1 and/or the wireless device of FIG. 6 can be provided; and

FIG. 8 is a flowchart of an exemplary process for configuring the multi-band acoustic multiplexer filter circuits of FIGS. 3 and 4.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include a multi-band acoustic multiplexer filter circuit. The multi-band acoustic multiplexer filter circuit includes multiple single-band acoustic filters and a multi-band filter circuit that can pass a signal in multiple passbands. In embodiments disclosed herein, the single-band acoustic filters and the multi-band filter circuit can be configured to collectively attenuate the signal in some of the passbands to thereby prevent the signal from becoming a blocking signal to any other passbands (e.g., adjacent passbands). By employing the multi-band filter circuit to provide a portion of the required attenuation to the blocking signal, each of the single-band acoustic filters can be subject to more relaxed attenuation requirements, thus making it possible to reduce complexity of the single-band acoustic filters and improve overall band rejection performance of the multi-band acoustic multiplexer filter circuit.

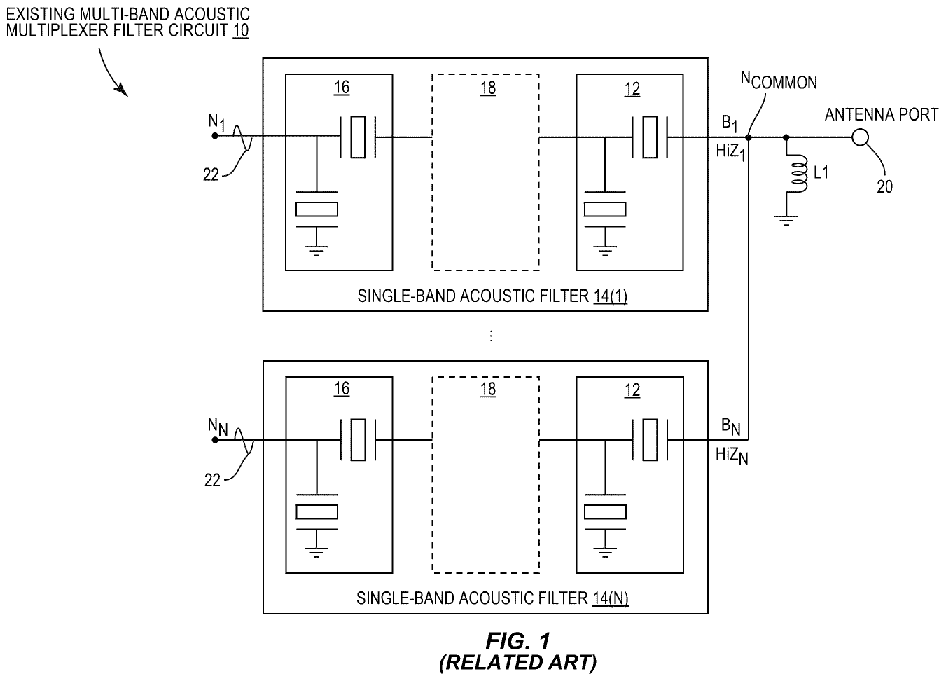

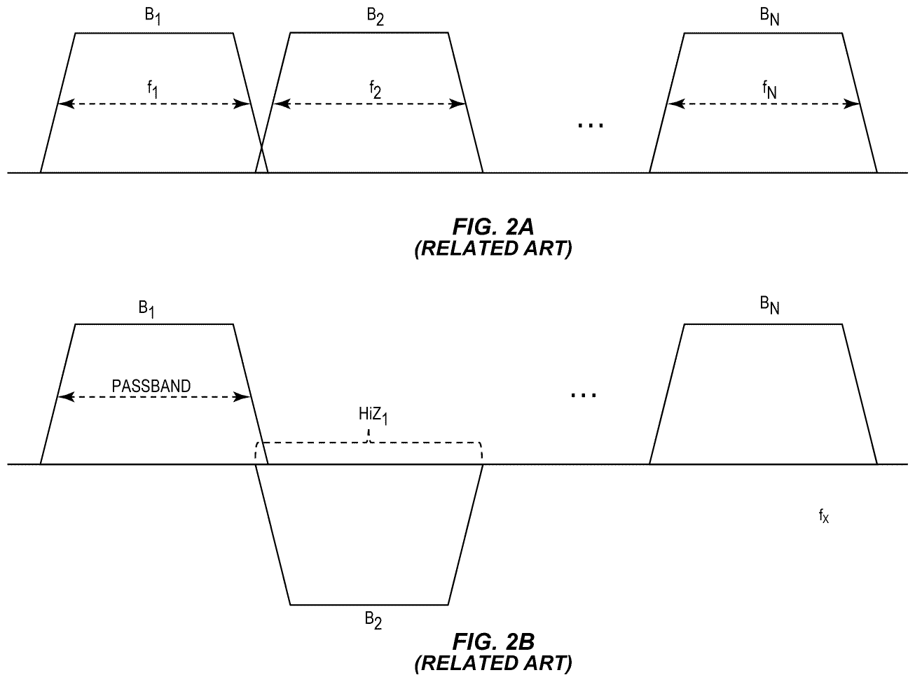

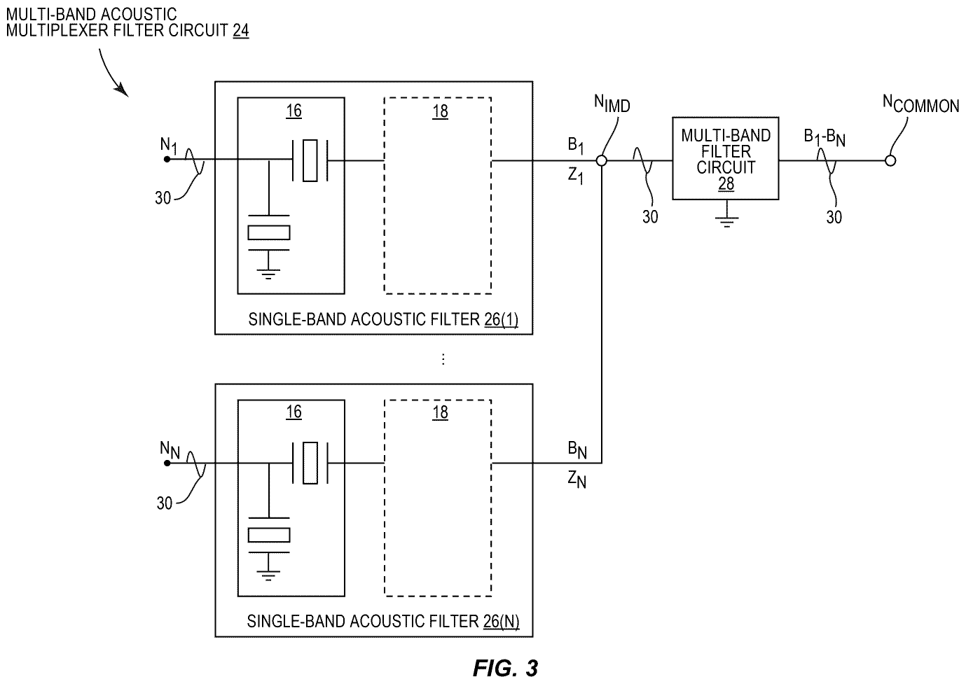

Before discussing the multi-band acoustic multiplexer filter circuit of the present disclosure, starting at FIG. 3, a brief overview of an existing multi-band acoustic multiplexer filter circuit is first provided with reference to FIGS. 1 and 2A-2B to help explain the technical problems to be solved by the multi-band acoustic multiplexer filter circuit of the present disclosure.

FIG. 1 is a schematic diagram of an exemplary existing multi-band acoustic multiplexer filter circuit 10 wherein an output stage resonator 12 in each of multiple single-band acoustic filters 14(1)-14(N) is coupled directly to a common node N_{COMMON}. Herein, each of the single-band acoustic filters 14(1)-14(N) also includes an input stage resonator 16. The input stage resonator 16 in each of the single-band acoustic filters 14(1)-14(N) is coupled to a respective one of multiple signal nodes N₁-N_{N}. Each of the single-band acoustic filters 14(1)-14(N) may also include an intermediate stage resonator(s) 18 that is coupled in between the input stage resonator 16 and the output stage resonator 12. The common node N_{COMMON}, on the other hand, may be coupled to an antenna port 20.

Each of the single-band acoustic filters 14(1)-14(N) is configured to pass a signal 22 from the respective one of the signal nodes N₁-N_{N} to the common node N_{COMMON} in a respective one of multiple passbands B₁-B_{N}. Outside the respective one of the passbands B₁-B_{N} (a.k.a. stopband), each of the single-band acoustic filters 14(1)-14(N) needs to shunt the signal 22 to thereby block the signal 22 from the common node N_{COMMON}.

FIG. 2A is a schematic diagram illustrating the passbands B₁-B_{N} of the single-band acoustic filters 14(1)-14(N) in FIG. 1. As shown herein, each of the single-band acoustic filters 14(1)-14(N) is configured to resonate at a respective one of multiple resonance frequencies f₁-f_{N} to pass the signal 22 in the respective one of the passbands B₁-B_{N}. As an example, the single-band acoustic filter 14(1) will pass the signal 22 in the respective passband B₁ and shunt the signal 22 outside the respective passband B₁ (e.g., passbands B₂-B_{N}).

In some cases, some of the passbands B₁-B_{N} may be close to, or even partially overlap with, some other ones of the passbands B₁-B_{N}. As an example, the two adjacent passbands B₁ and B₂ are partially overlapped. As a result, the signal 22 that is normally passed to the common node N_{COMMON} in the passband B₁ may become a blocking signal in the passband B₂. Likewise, the signal 22 that is normally passed to the common node N_{COMMON} in the passband B₂ may become the blocking signal in the passband B₁. In other words, the passband B₁ may become a blocking passband to the passband B₂ and the passband B₂ may become a blocking passband to the passband B₁. Understandably from the example, any of the passbands B₁-B_{N} may become a blocking passband(s) to any other one(s) of the passbands B₁-B_{N}.

As such, each of the single-band acoustic filters 14(1)-14(N) must also present a respective one of multiple high impedances HiZ₁-HiZ_{N} at the common node N_{COMMON} to thereby prevent the signal 22 from becoming the blocking signal in any of the passbands B₁-B_{N}. As an example, FIG. 2B shows a scenario wherein the single-band acoustic filter 14(1) in FIG. 1 presents the respective high impedance HiZ₁ in the passband B₂ to prevent the signal 22 from becoming the blocking signal in the respective passband B₁.

Understandably, to prevent the signal 22 from becoming the blocking signal in any of the passbands B₁-B_{N}, each of the single-band acoustic filters 14(1)-14(N) must provide adequate out-of-band (OOB) rejection to the signal 22 at the common node N_{COMMON}. As a result, each of the single-band acoustic filters 14(1)-14(N) may be subject to a more stringent OOB rejection requirement that can potentially increase complexity of the single-band acoustic filters 14(1)-14(N). In this regard, the technical problem to be solved herein is to optimize and simplify the single-band acoustic filters 14(1)-14(N) and provide adequate OOB rejection in any of the passbands B₁-B_{N} to prevent the respective passband from becoming a blocking passband to any other of the passbands B₁-B_{N}.

In this regard, FIG. 3 is a schematic diagram of an exemplary multi-band acoustic multiplexer filter circuit 24 wherein multiple single-band acoustic filters 26(1)-26(N) and a multi-band filter circuit 28 are configured according to an embodiment of the present disclosure to collectively provide adequate OOB attenuation to a signal 30 at the output common node N_{COMMON} and in any of the multiple passbands B₁-B_{N}. In an embodiment, each of the single-band acoustic filters 26(1)-26(N) retains the input stage resonator 16 and, optionally, the intermediate acoustic resonator 18 from the existing acoustic multiplexer filter circuit 10. The multi-band filter circuit 28, on the other hand, replaces the output stage resonator 12 in each of the single-band acoustic filters 14(1)-14(N) in

FIG. 1 and functions as a common output stage resonator to each of the single-band acoustic filters 26(1)-26(N).

Herein, the input stage resonator 16 in each of the single-band acoustic filters 26(1)-26(N) is coupled to a respective one of the multiple signal nodes N₁-N_{N} and the multi-band filter circuit 28 is coupled between an intermediate common node N_{IMD} and the output common node N_{COMMON}. In this embodiment, each of the single-band acoustic filters 26(1)-26(N) is coupled to the intermediate common node N_{IMD}. As such, each of the single-band acoustic filters 26(1)-26(N) is configured to pass the signal 30 between the respective one of the signal nodes N₁-N_{N} and the intermediate common node N_{IMD} in a respective one of the passbands B₁-B_{N} and block (a.k.a. shunt) the signal 30 between the respective one of the signal nodes N₁-N_{N} and the intermediate common node N_{IMD} outside the respective one of the passbands B₁-B_{N}.

To help provide the OOB rejection in any of the passbands B₁-B_{N}, each of the single-band acoustic filters 26(1)-26(N) is further configured to present a respective one of multiple impedances Z₁-Z_{N} at the intermediate common node N_{IMD} to help attenuate the signal 30 in any blocking passband(s) to the respective one of the passbands B₁-B_{N}. As an example, in the scenario illustrated in FIG. 2B, the single-band acoustic filter 26 (1) is configured to present the respective impedance Z₁ at the intermediate common node N_{IMD} to thereby attenuate the signal 30 in the passband B₂, which is a blocking passband to the respective passband B₁. Likewise, the single-band acoustic filter 26(2) is configured to present the respective impedance Z₂ at the intermediate common node N_{IMD} to thereby attenuate the signal 30 in the blocking passband B₁, which is a blocking passband to the respective passband B₂.

The multi-band filter circuit 28 is configured to receive the signal 30 in any of the passbands B₁-B_{N} via the intermediate common node N_{IMD} and pass the received signal 30 to the output common node N_{COMMON}. In an embodiment, the multi-band filter circuit 28 is configured to further attenuate the signal 30 at the output common node N_{COMMON} in any of the passbands B₁-B_{N} that may become a blocking passband to any other one(s) of the passbands B₁-B_{N}. In this regard, in the scenario of FIG. 2B, the multi-band filter circuit 28 will further attenuate the signal 30 in the passbands B₁ and B₂.

Because the multi-band filter circuit 28 can share the burden in providing the required attenuation at the output common node N_{COMMON}, each of the single-band acoustic filters 26(1)-26(N) will be subject to a more relaxed OOB rejection requirement. Accordingly, the impedances Z₁-Z_{N} presented at the intermediate common node N_{IMD} may be less than the high impedances HiZ₁-HiZ_{N} in FIG. 1. As a result, the single-band acoustic filters 26(1)-26(N) herein can be optimized, both in complexity and reliability, over the single-band acoustic filters 14(1)-14(N) in the existing acoustic multiplexer filter circuit 10.

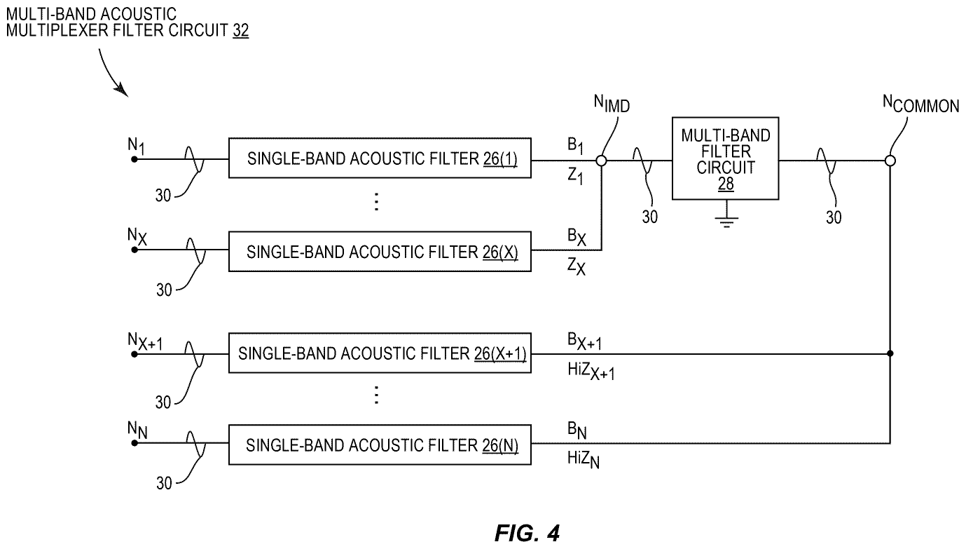

Alternative to coupling all of the single-band acoustic filters 26(1)-26(N) to the intermediate common node N_{IMD}, it is also possible to couple some of the signal-band acoustic filters 26(1)-26(N) directly to the output common node N_{COMMON}. In this regard, FIG. 4 is a schematic diagram of an exemplary multi-band acoustic multiplexer filter circuit 32 wherein some of the single-band acoustic filters 26(1)-26(N) and the multi-band filter circuit 28 are configured according to another embodiment of the present disclosure to collectively provide adequate OOB attenuation to the signal 30 at the output common node N_{COMMON} and in any of the passbands B₁-B_{N}. Common elements between FIGS. 3 and 4 are shown therein with common element numbers and will not be re-described herein.

In this embodiment, a first subset of the single-band acoustic filters 26(1)-26(X) (a.k.a. “one or more first single-band acoustic filters”) among the single-band acoustic filters 26(1)-26(N) is coupled to the intermediate common node N_{IMD}, whereas a second subset of the single-band acoustic filters 26(X+1)-26(N) (a.k.a. “one or more second single-band acoustic filters”) among the single-band acoustic filters 26(1)-26(N) are coupled directly to the output common node N_{COMMON}. In this regard, the multi-band filter circuit 28 and each of the first subset of the single-band acoustic filters 26(1)-26(X) are configured to collectively provide adequate OOB attenuation to the signal 30 at the output common node N_{COMMON} and in any of the passbands B₁-B_{X} (a.k.a. “first passbands”). Accordingly, each of the first subset of the single-band acoustic filters 26(1)-26(X) can present a respective one of one or more impedances Z₁-Z_{X} (a.k.a. “first impedances”) at the intermediate common node N_{IMD} in any blocking passband(s) to a respective one of the passbands B₁-B_{X}.

In contrast, the second subset of the single-band acoustic filters 26(X+1)-26(N) are coupled directly to the output common node N_{COMMON}, bypassing the multi-band filter circuit 28. As such, each of the single-band acoustic filters 26 (X+1)-26 (N) will operate independently from the multi-band filter circuit 28. In this regard, each of the second subset of the single-band acoustic filters 26(X+1)-26(N) needs to present a respective one of multiple high impedances HiZ_{X+1}-HiZ_{N} (a.k.a. “second impedances”) at the output common node N_{COMMON} in any blocking passband(s) to a respective one of the passbands B_{X+1}-B_{N} (a.k.a. “second passbands”). In an embodiment, each of the high impedances HiZ_{X+1}-HiZ_{N} needs to be higher that any of the impedances Z₁-Z_{X}.

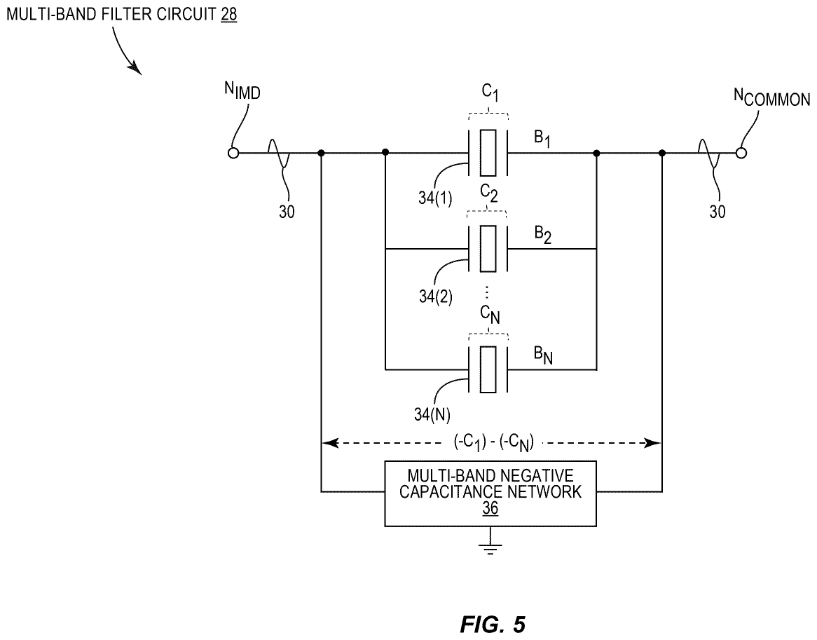

FIG. 5 is a schematic diagram providing an exemplary illustration of the multi-band filter circuit 28 in the multi-band acoustic multiplexer filter circuit 24 of FIG. 3 and the multi-band acoustic multiplexer filter circuit 32 of FIG. 4. Common elements between FIGS. 3, 4, and 5 are shown therein with common element numbers and will not be re-described herein.

In an embodiment, the multi-band filter circuit 28 includes multiple acoustic resonators 34(1)-34(N). The acoustic resonators 34(1)-34(N) are coupled in parallel between the intermediate common node N_{IMD} and the output common node N_{COMMON}. Specifically, each of the acoustic resonators 34(1)-34(N) is configured to pass the signal 30 between the intermediate common node N_{IMD} and the output common node N_{COMMON} in a respective one of the passbands B₁-B_{N}.

Notably, each of the acoustic resonators 34(1)-34(N) can inherently present a respective one of multiple equivalent capacitances C₁-C_{N} between the intermediate common node N_{IMD} and the output common node N_{COMMON}. Since the equivalent capacitances C₁-C_{N} may reduce the ability of the multi-band filter circuit 28 in blocking the signal 30 outside the passbands B₁-B_{N}, the multi-band filter circuit 28 further includes a multi-band negative capacitance network 36, which is coupled between the intermediate common node N_{IMD} and the output common node N_{COMMON}. The multi-band negative capacitance network 36 is configured to present a respective one of multiple negative capacitances (−C₁)-(−C_{N}) between the intermediate common node N_{IMD} and the output common node N_{COMMON} to thereby offset the equivalent capacitances C₁-C_{N} in the passbands B₁-B_{N}.

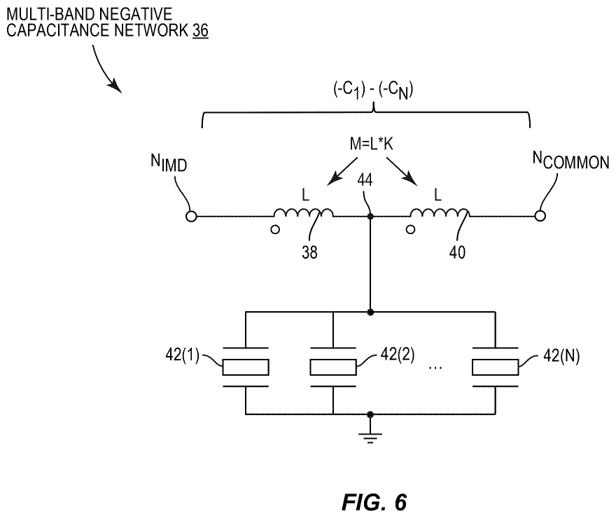

The multi-band negative capacitance network 36 can be implemented as an active network or a passive network. As an example, FIG. 6 is a schematic diagram providing an exemplary illustration of the multi-band negative capacitance network 36 in the multi-band filter circuit 28 of FIG. 5. Common elements between FIGS. 5 and 6 are shown therein with common element numbers and will not be re-described herein.

Herein, the multi-band negative capacitance network 36 includes a pair of negatively coupled inductors 38 (a.k.a. first inductor), 40 (a.k.a. second inductor) and multiple shunt resonators 42(1)-42(N). The first inductor 38 is coupled between the intermediate common node N_{IMD} and a middle node 44. The second inductor 40 is coupled between the middle node 44 and the output common node N_{COMMON}. The first inductor 38 and the second inductor 40 each has an inductance L and collectively provide a mutual inductance M based on a coupling factor K (0<K<1). The shunt resonators 42(1)-42(N) are coupled in parallel between the middle node 44 and a ground. Each of the shunt resonators 42(1)-42(N) can be configured to shunt the signal 30 to the ground outside a respective one of the passbands B₁-B_{N}. Each of the shunt resonators 42(1)-42(N) can be further tuned to cause the multi-band negative capacitance network 36 to provide a respective one of the negative capacitances (−C₁)-(−C_{N}) between the intermediate common node N_{IMD} and the output common node N_{COMMON}.

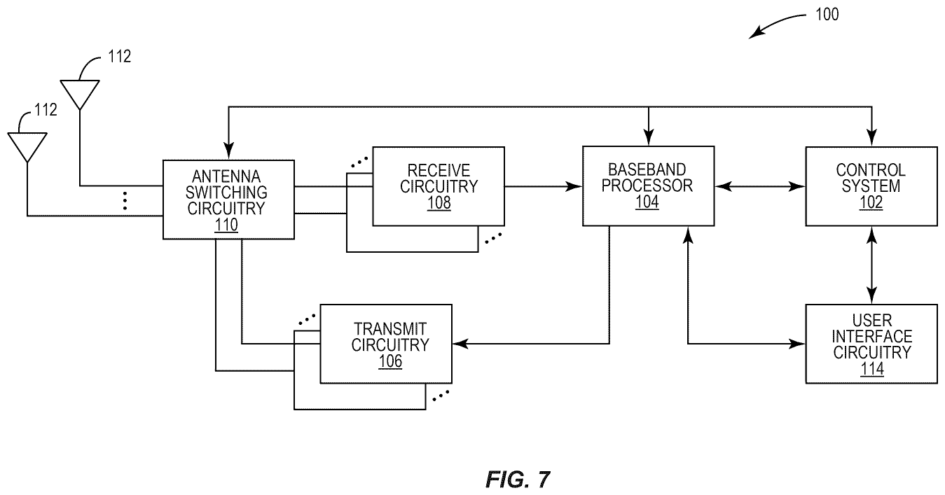

The multi-band acoustic multiplexer filter circuit 24 of FIG. 3 and the multi-band acoustic multiplexer filter circuit 32 of FIG. 4 can be provided in a user element (e.g., a wireless device) to support the embodiments described above. In this regard, FIG. 7 is a schematic diagram of an exemplary user element 100 wherein the multi-band acoustic multiplexer filter circuit 24 of FIG. 3 and the multi-band acoustic multiplexer filter circuit 32 of FIG. 4 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In an embodiment, the multi-band acoustic multiplexer filter circuit 24 of FIG. 3 and the multi-band acoustic multiplexer filter circuit 32 of FIG. 4 can be provided in the antenna switching circuitry 110. In this regard, the output common node N_{COMMON} may be coupled to any of the antennas 112.

In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

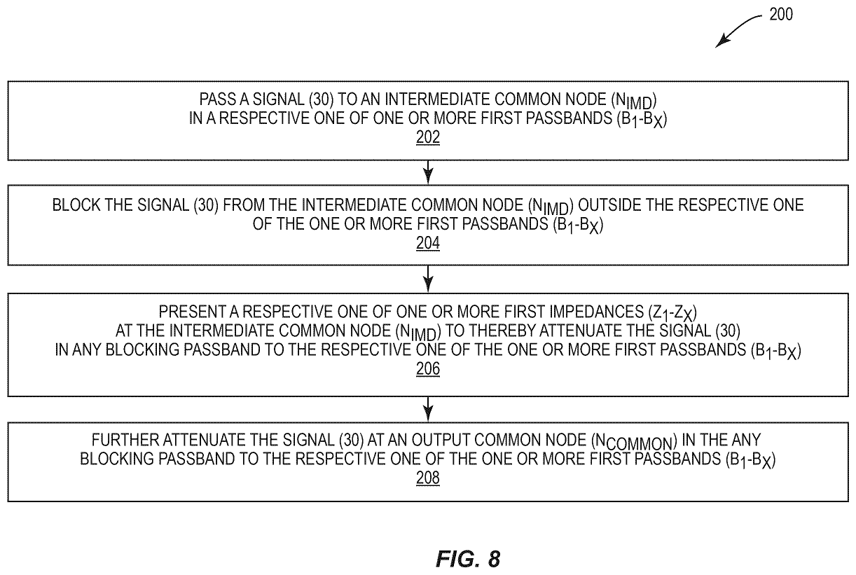

The multi-band acoustic multiplexer filter circuit 24 of FIG. 3 and the multi-band acoustic multiplexer filter circuit 32 of FIG. 4 can be configured according to a process. In this regard, FIG. 8 is a flowchart of an exemplary process 200 for configuring the multi-band acoustic multiplexer filter circuit 24 of FIG. 3 and the multi-band acoustic multiplexer filter circuit 32 of FIG. 4.

Herein, the process 200 includes passing the signal 30 to the intermediate common node N_{IMD} in a respective one of the first passbands B₁-B_{X} (step 202). The process 200 also includes blocking the signal 30 from the intermediate common node N_{IMD} outside the respective one of the first passbands B₁-B_{X} (step 204). The process 200 also includes presenting a respective one of the first impedances Z₁-Z_{X} at the intermediate common node N_{IMD} to thereby attenuate the signal 30 in any blocking passband to the respective one of the first passbands B₁-B_{X} (step 206). The process 200 also includes further attenuating the signal 30 at the output common node N_{COMMON} in the any blocking passband to the respective one of the first passbands B₁-B_{X} (step 208).

Those skilled in the art will recognize improvements and modifications to the embodiments of the present disclosure. All such improvements and modifications are considered within the scope of the concepts disclosed herein and the claims that follow.

What is claimed is:

1. A multi-band acoustic multiplexer filter circuit comprising:
one or more first single-band acoustic filters each coupled to an intermediate common node and configured to:
pass a signal to the intermediate common node in a respective one of one or more first passbands;
block the signal from the intermediate common node outside the respective one of the one or more first passbands; and
present a respective one of one or more first impedances at the intermediate common node to thereby attenuate the signal in any blocking passband to the respective one of the one or more first passbands; and
a multi-band filter circuit coupled between the intermediate common node and an output common node and configured to:
receive the signal via the intermediate common node in the one or more first passbands and pass the received signal to the output common node; and
further attenuate the received signal at the output common node in the any blocking passband to the respective one of the one or more first passbands.

2. The multi-band acoustic multiplexer filter circuit of claim 1, further comprising one or more second single-band acoustic filters each coupled directly to the output common node and configured to:
pass the signal directly to the output common node in a respective one of one or more second passbands;
block the signal directly from the output common node outside the respective one of the one or more second passbands; and
present a respective one of one or more second impedances at the output common node to thereby attenuate the signal in any blocking passband to the respective one of the one or more second passbands.

3. The multi-band acoustic multiplexer filter circuit of claim 2, wherein the one or more second impedances are each higher than any of the one or more first impedances.

4. The multi-band acoustic multiplexer filter circuit of claim 1, wherein the multi-band filter circuit comprises:
one or more resonators coupled in parallel between the intermediate common node and the output common node and each configured to pass the signal between the intermediate common node and the output common node in a respective one of the one or more first passbands; and
a multi-band negative capacitance network coupled between the intermediate common node and the output common node and configured to present a negative capacitance between the intermediate common node and the output common node in each of the one or more first passbands.

5. The multi-band acoustic multiplexer filter circuit of claim 4, wherein the multi-band negative capacitance network comprises:
a pair of negatively coupled inductors provided in series between the intermediate common node and the output common node; and
one or more shunt resonators coupled in parallel between a middle node located between the pair of negatively coupled inductors and a ground and each tuned to provide a respective one of one or more negative capacitances to shunt the signal to the ground outside a respective one of the one or more first passbands.

6. The multi-band acoustic multiplexer filter circuit of claim 1, wherein each of the one or more first single-band acoustic filters comprises:
a respective one of one or more input stage resonators; and
a common output stage resonator consisting of the multi-band filter circuit.

7. A wireless device comprising a multi-band acoustic multiplexer filter circuit, the multi-band acoustic multiplexer filter circuit comprises:
one or more first single-band acoustic filters each coupled to an intermediate common node and configured to:
pass a signal to the intermediate common node in a respective one of one or more first passbands;
block the signal from the intermediate common node outside the respective one of the one or more first passbands; and
present a respective one of one or more first impedances at the intermediate common node to thereby attenuate the signal in any blocking passband to the respective one of the one or more first passbands; and
a multi-band filter circuit coupled between the intermediate common node and an output common node and configured to:
receive the signal via the intermediate common node in the one or more first passbands and pass the received signal to the output common node; and
further attenuate the received signal at the output common node in the any blocking passband to the respective one of the one or more first passbands.

8. The wireless device of claim 7, wherein the multi-band acoustic multiplexer filter circuit further comprises one or more second single-band acoustic filters each coupled directly to the output common node and configured to:
pass the signal directly to the output common node in a respective one of one or more second passbands;
block the signal directly from the output common node outside the respective one of the one or more second passbands; and
present a respective one of one or more second impedances at the output common node to thereby attenuate the signal in any blocking passband to the respective one of the one or more second passbands.

9. The wireless device of claim 8, wherein the one or more second impedances are each higher than any of the one or more first impedances.

10. The wireless device of claim 8, wherein the multi-band filter circuit comprises:
one or more resonators coupled in parallel between the intermediate common node and the output common node and each configured to pass the signal between the intermediate common node and the output common node in a respective one of the one or more first passbands; and
a multi-band negative capacitance network coupled between the intermediate common node and the output common node and configured to present a negative capacitance between the intermediate common node and the output common node in each of the one or more first passbands.

11. The wireless device of claim 10, wherein the multi-band negative capacitance network comprises:
a pair of negatively coupled inductors provided in series between the intermediate common node and the output common node; and
one or more shunt resonators coupled in parallel between a middle node located between the pair of negatively coupled inductors and a ground and each tuned to provide a respective one of one or more negative capacitances to shunt the signal to the ground outside a respective one of the one or more first passbands.

12. The wireless device of claim 7, wherein each of the one or more first single-band acoustic filters comprises:
a respective one of one or more input stage resonators; and
a common output stage resonator consisting of the multi-band filter circuit.

13. The wireless device of claim 7, wherein the output common node is coupled to an antenna port.

14. A method for configuring a multi-band acoustic multiplexer filter circuit comprising:
passing a signal to an intermediate common node in a respective one of one or more first passbands;
blocking the signal from the intermediate common node outside the respective one of the one or more first passbands;
presenting a respective one of one or more first impedances at the intermediate common node to thereby attenuate the signal in any blocking passband to the respective one of the one or more first passbands; and
further attenuating the signal at an output common node in the any blocking passband to the respective one of the one or more first passbands.

15. The method of claim 14, further comprising:
passing the signal directly to the output common node in a respective one of one or more second passbands;
blocking the signal directly from the output common node outside the respective one of the one or more second passbands; and
presenting a respective one of one or more second impedances at the output common node to thereby attenuate the signal in any blocking passband to the respective one of the one or more second passbands.

16. The method of claim 15, wherein the one or more second impedances are each higher than any of the one or more first impedances.
